(19) United States
(12) Patent Application Publication
(10) Pub. No.: US 2026/0301780 A1
(43) Pub. Date: Oct. 1, 2026

(54) DYNAMIC VOLTAGE MANAGEMENT IN SOLID-STATE DRIVES

(71) Applicant: SK Hynix NAND Product Solutions Corp. (dba Solidigm), Rancho Cordova, CA (US)

(72) Inventors: Adrian MOCANU, Langley (CA); Zeljko ZUPANC, Richmond (CA); Ben SOMMERFELD, Vancouver (CA); Preethi SOMESWARAN, Fremont, CA (US)

(21) Appl. No.: 19/089,636

(22) Filed: Mar. 25, 2025

(51) Int. Cl. G11C 5/14

(52) U.S. Cl. CPC G11C 5/144

(57) ABSTRACT

This application is directed to adaptively powering of a power loss protection (PLP) capacitor of an electronic device. The electronic device includes a load interface, the PLP capacitor, a PLP circuit, a capacitance measurement component, and a controller. The load interface is configured to supply an operating supply voltage to a load. The PLP capacitor is configured to store electric energy provided to power the load when a primary power source is unavailable, and the PLP circuit is configured to charge the PLP capacitor to a first supply voltage and store the electric energy when a primary power source of the load is available. The capacitance measurement component is configured to generate capacitance data indicating a capacitance of the PLP capacitor. The controller is configured to control charging of the PLP capacitor and adjust the first supply voltage of the PLP capacitor based on the capacitance of the PLP capacitor.

### TECHNICAL FIELD

This application relates generally to electronic technology including, but not limited to, methods, systems, and devices for managing energy stored in capacitors for hardware power loss protection of electronic devices (e.g., a solid-state drive).

### BACKGROUND

Memory is applied in a computer system to store instructions and data. The data are processed by one or more processors of the computer system according to the instructions stored in the memory. Multiple memory units are used in different portions of the computer system to serve different functions. Specifically, the computer system includes non-volatile memory that acts as secondary memory to keep data stored thereon if the computer system is decoupled from a power source. Examples of the secondary memory include, but are not limited to, hard disk drives (HDDs) and solid-state drives (SSDs). The secondary memory relies on a memory controller to manage its memory space and process read, write, and read-modify-write requests from a host device efficiently with low latency. Power loss protection (PLP) in SSDs is a safeguard that ensures data integrity during sudden power failures. It typically involves capacitors or supercapacitors that provide temporary power, allowing a memory controller to flush in-flight data from volatile memory (e.g., DRAM) to non-volatile memory before losing power. While effective, one major issue with PLP capacitors is degradation over time. These capacitors can gradually lose their ability to hold sufficient charge due to aging, thermal stress, or repeated power cycling, potentially compromising the secondary memory's ability to protect data during unexpected shutdowns. Regular monitoring and quality control are crucial to mitigate this risk.

### SUMMARY

Various embodiments of this application are directed to methods, system, and devices for adaptively powering a PLP capacitor during a lifetime of a memory device (e.g., an SSD). A PLP circuit is configured to measure the capacitance of the PLP capacitor, and an operating voltage of the PLP capacitor is dynamically adjusted to make the PLP capacitor store sufficient energy (e.g., a target energy) for PLP of the memory device. Given the target energy, a current voltage level of the PLP capacitor is measured, and the capacitance of the PLP capacitor is determined based on the voltage level of the PLP capacitor. As the capacitance of the PLP capacitor varies with a service time of the memory device, Dynamic Voltage Management (DVM) is implemented to adjust the operating voltage of the PLP capacitor adaptively based on the determined capacitance of the PLP capacitor. By these means, the PLP capacitor does not need to be overprovisioned with a substantially high voltage level to provide sufficient energy (e.g., greater than a target amount of energy) during the service time of the memory device, thereby significantly minimizing an aging effect, extending a lifetime of the PLP capacitor, and avoiding usage of excessive backup capacitors.

In one aspect, some implementations include an electronic device. The electronic device includes a load interface, a power loss protection (PLP) capacitor, a PLP circuit, a capacitance measurement component, and a controller. The load interface is configured to supply an operating supply voltage to a load. The PLP capacitor is coupled to the load interface, and configured to store electric energy provided to power the load when a primary power source is unavailable. The PLP circuit is coupled to the load interface and the PLP capacitor, and configured to charge the PLP capacitor to a first supply voltage and store the electric energy when a primary power source of the load is available. The capacitance measurement component is coupled to the PLP capacitor, and configured to generate capacitance data indicating a capacitance of the PLP capacitor. The controller is coupled to the capacitance measurement component and the PLP circuit, and configured to control charging of the PLP capacitor and adjust the first supply voltage of the PLP capacitor based on the capacitance of the PLP capacitor.

In another aspect, some implementations include an integrated circuit. The integrated circuit further includes a load interface configured to supply an operating supply voltage to a load, a power loss protection (PLP) capacitor coupled to the load interface, and a PLP circuit coupled to the load interface and the PLP capacitor. The PLP capacitor is configured to store electric energy provided to power the load when a primary power source is unavailable. The PLP circuit is configured to, when a primary power source of the load is available, charge the PLP capacitor to a first supply voltage and store the electric energy in the PLP capacitor, generate capacitance data indicating a capacitance of the PLP capacitor, and adjust the first supply voltage of the PLP capacitor based on the capacitance of the PLP capacitor.

In yet another aspect, a method is implemented to adaptively powering a power loss protection (PLP) capacitor of an electronic device. The method includes generating a first supply voltage by a PLP circuit, charging a PLP capacitor with the first supply voltage to store electric energy in the PLP capacitor, generating a capacitance data indicating a capacitance of the PLP capacitor, controlling charging of the PLP capacitor to adjust the first supply voltage of the PLP capacitor based on the capacitance of the PLP capacitor, and applying the electric energy stored by in PLP capacitor to power a load when a primary power source of the load is unavailable.

These illustrative embodiments and implementations are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a block diagram of an example system module in a typical electronic system in accordance with some embodiments.

FIG. 2 is a block diagram of a memory system of an example electronic device, in accordance with some embodiments.

FIG. 3A is a block diagram of an example power management system having an operation mode in which a PLP capacitor is charged, in accordance with some embodiments.

FIG. 3B is a block diagram of an example power management system having a PLP mode in which a PLP capacitor discharges to provide power, in accordance with some embodiments.

FIG. 4 is a temporal diagram of an example first supply voltage of a PLP capacitor during a startup phase and a runtime phase, in accordance with some embodiments.

FIG. 5 is a diagram showing a change of electrical energy stored in an PLP capacitor, in accordance with some embodiments.

FIG. 6 is a flow diagram of an example method for powering of a PLP capacitor of an electronic device, in accordance with some embodiments.

Like reference numerals refer to corresponding parts throughout the several views of the drawings.

### DETAILED DESCRIPTION

Reference will now be made in detail to specific embodiments, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details. For example, it will be apparent to one of ordinary skill in the art that the subject matter presented herein can be implemented on many types of electronic devices with storage capabilities.

A memory device (e.g., SSD) includes a PLP circuit and a PLP capacitor or a bank of PLP capacitors coupled to the PLP circuit. At least the target amount of energy is stored in the PLP capacitor or the bank of PLP capacitors, and applied to complete a PLP phase of the memory device when a disconnection from a power source occurs. In some embodiments, a size, a voltage level, or both of the PLP capacitor are adjusted to provide the target amount of energy. In some embodiments, the PLP capacitor can be Tantalum Polymer (Ta-P) types, and Ta-P has an operation lifetime that depends on an operating voltage and/or temperature. A capacitance of the PLP capacitor may decrease over time due to aging of Ta-P during its operation lifetime. In some embodiments, the PLP capacitor is overprovisioned with a substantially high voltage level to provide sufficient energy (e.g., greater than the target amount of energy), e.g., at any time of the PLP capacitor's operation lifetime. Further, in some situations, this high voltage level may continue to increase over time to account for a capacitance loss over a memory service life (e.g., 5 years). Energy stored in the PLP capacitor is proportional to a product of a capacitance of the PLP capacitor and a square of the voltage level of the PLP capacitor. In accordance with some embodiments of this application is at least a realization that overprovisioning of the PLP capacitor with the substantially high voltage accelerates aging of the PLP capacitor and requires a higher voltage to compensate for capacitor aging or additional fallback capacitors to share a task of storing sufficient energy for PLP.

Various embodiments of this application are directed to methods, system, and devices for adaptively powering a PLP capacitor based on associated capacitance during a lifetime of a memory device (e.g., an SSD). Capacitance of the PLP capacitor decreases during the lifetime of the memory device, and a voltage level of the PLP capacitor increases to compensate a capacitance drop of the PLP capacitor. In some embodiments, a PLP circuit is configured to measure the capacitance of the PLP capacitor, and an operating voltage of the PLP capacitor is dynamically adjusted to make the PLP capacitor store sufficient energy for PLP of the memory device. A target energy stored in the PLP capacitor is proportional to a product of the capacitance of the PLP capacitor and a square of the voltage level of the PLP capacitor. Given the target energy is known, the voltage level of the PLP capacitor is measured, and the capacitance of the PLP capacitor is determined based on the voltage level of the PLP capacitor. As the capacitance of the PLP capacitor varies with a service time of the memory device, dynamic voltage management (DVM) is implemented to adjust an operating voltage of the PLP capacitor by measuring the voltage level of the PLP capacitor and determining the capacitance of the PLP capacitor. By these means, the PLP capacitor does not need to be overprovisioned with a substantially high voltage level to provide sufficient energy (e.g., greater than a target amount of energy) during the service time of the memory device, thereby significantly minimizing an aging effect, extending a lifetime of the PLP capacitor, and avoiding usage of excessive backup capacitors.

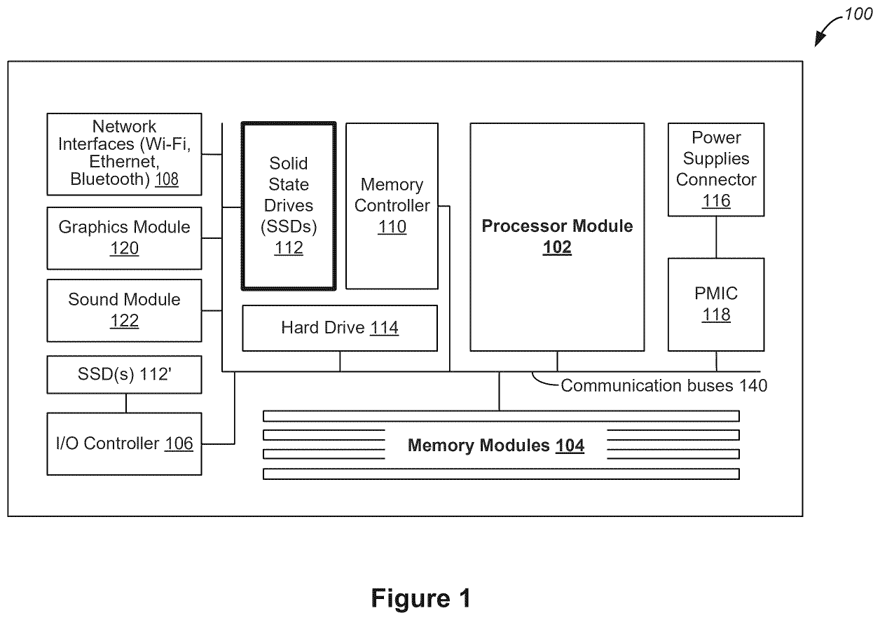

FIG. 1 is a block diagram of an example system module 100 in a typical electronic system in accordance with some embodiments. The system module 100 in this electronic system includes at least a processor module 102, memory modules 104 for storing programs, instructions and data, an input/output (I/O) controller 106, one or more communication interfaces such as network interfaces 108, and one or more communication buses 140 for interconnecting these components. In some embodiments, the I/O controller 106 allows the processor module 102 to communicate with an I/O device (e.g., a keyboard, a mouse or a trackpad) via a universal serial bus interface. In some embodiments, the network interfaces 108 includes one or more interfaces for Wi-Fi, Ethernet and Bluetooth networks, each allowing the electronic system to exchange data with an external source, e.g., a server or another electronic system. In some embodiments, the communication buses 140 include circuitry (sometimes called a chipset) that interconnects and controls communications among various system components included in system module 100.

In some embodiments, the memory modules 104 include high-speed random-access memory, such as static random-access memory (SRAM), double data rate (DDR) dynamic random-access memory (DRAM), or other random-access solid state memory devices. In some embodiments, the memory modules 104 include non-volatile memory, such as one or more magnetic disk storage devices, optical disk storage devices, flash storage devices, or other non-volatile solid state storage devices. In some embodiments, the memory modules 104, or alternatively the non-volatile storage device(s) within the memory modules 104, include a non-transitory computer readable storage medium. In some embodiments, memory slots are reserved on the system module 100 for receiving the memory modules 104. Once inserted into the memory slots, the memory modules 104 are integrated into the system module 100.

In some embodiments, the system module 100 further includes one or more components selected from a memory controller 110, SSD(s) 112, an HDD 114, power management integrated circuit (PMIC) 118, a graphics module 120, and a sound module 122. The memory controller 110 is configured to control communication between the processor module 102 and memory components, including the memory modules 104, in the electronic system. The SSD(s) 112 are configured to apply integrated circuit assemblies to store data in the electronic system, and in many embodiments, are based on NAND or NOR memory configurations. The HDD 114 is a conventional data memory device used for storing and retrieving digital information based on electromechanical magnetic disks. The power supply connector 116 is electrically coupled to receive an external power supply. The PMIC 118 is configured to modulate the received external power supply to other desired DC voltage levels, e.g., 5V, 3.3V or 1.8V, as required by various components or circuits (e.g., the processor module 102) within the electronic system. The graphics module 120 is configured to generate a feed of output images to one or more display devices according to their desirable image/video formats. The sound module 122 is configured to facilitate the input and output of audio signals to and from the electronic system under control of computer programs.

Alternatively or additionally, in some embodiments, the system module 100 further includes SSD(s) 112′ coupled to the I/O controller 106 directly. Conversely, the SSDs 112 are coupled to the communication buses 140. In an example, the communication buses 140 operates in compliance with Peripheral Component Interconnect Express (PCIe or PCI-E), which is a serial expansion bus standard for interconnecting the processor module 102 to, and controlling, one or more peripheral devices and various system components including components 110-122.

Further, one skilled in the art knows that other non-transitory computer readable storage media can be used, as new data storage technologies are developed for storing information in the non-transitory computer readable storage media in the memory modules 104, SSD(s) 112 or 112′, and HDD 114. These new non-transitory computer readable storage media include, but are not limited to, those manufactured from biological materials, nanowires, carbon nanotubes and individual molecules, even though the respective data storage technologies are currently under development and yet to be commercialized.

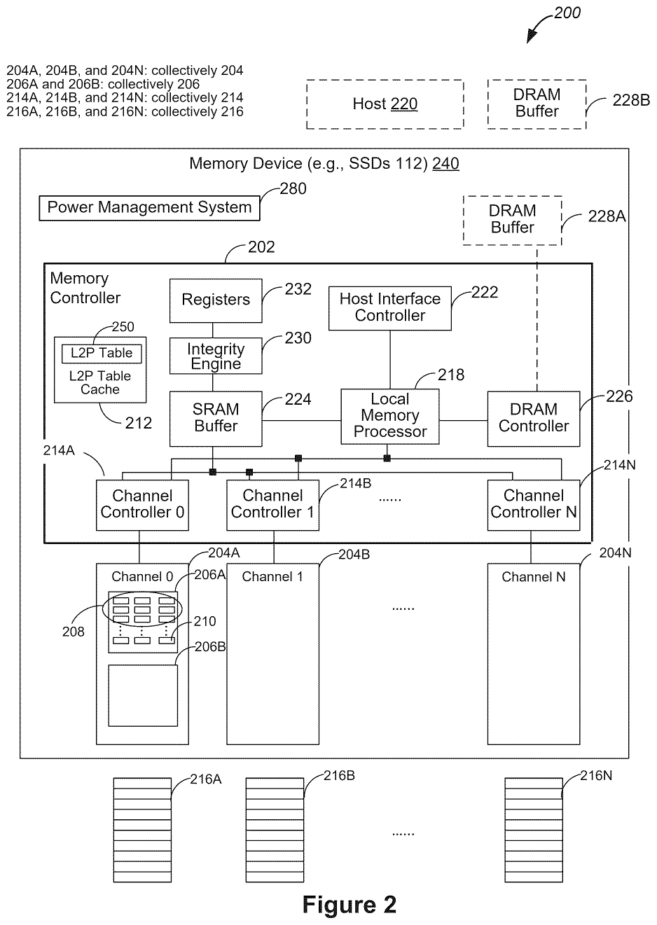

FIG. 2 is a block diagram of a memory system 200 of an example electronic device, in accordance with some embodiments. The memory system 200 is coupled to a host device 220 (e.g., a processor module 102 in FIG. 1) and configured to store instructions and data for an extended time, e.g., when the electronic device sleeps, hibernates, or is shut down. The host device 220 is configured to access the instructions and data stored in the memory system 200 and process the instructions and data to run an operating system (OS) and execute applications. The memory system 200 includes one or more memory devices 240 (e.g., SSD(s)). Each memory device 240 further includes a controller 202 and a plurality of memory channels 204 (e.g., channel 204A, 204B, and 204N). Each memory channel 204 includes a plurality of memory cells. The controller 202 is configured to execute firmware level software to bridge the plurality of memory channels 204 to the host device 220. In some embodiments, each memory device 240 is formed on a printed circuit board (PCB).

Each memory channel 204 includes one or more memory packages 206 (e.g., two memory dies). In an example, each memory package 206 (e.g., memory package 206A or 206B) corresponds to a memory die. Each memory package 206 includes a plurality of memory planes 208, and each memory plane 208 further includes a plurality of memory pages 210. Each memory page 210 includes an ordered set of memory cells, and each memory cell is identified by a respective physical address. In some embodiments, the memory device 240 includes a plurality of superblocks. Each superblock includes a plurality of memory blocks each of which further includes a plurality of memory pages 210. For each superblock, the plurality of memory blocks are configured to be written into and read from the memory system via a memory input/output (I/O) interface concurrently. Optionally, each superblock groups memory cells that are distributed on a plurality of memory planes 208, a plurality of memory channels 204, and a plurality of memory dies 206. In an example, each superblock includes at least one set of memory pages, where each page is distributed on a distinct one of the plurality of memory dies 206, has the same die, plane, block, and page designations, and is accessed via a distinct channel of the distinct memory die 206. In another example, each superblock includes at least one set of memory blocks, where each memory block is distributed on a distinct one of the plurality of memory dies 206 includes a plurality of pages, has the same die, plane, and block designations, and is accessed via a distinct channel of the distinct memory die 206. The memory device 240 stores information of an ordered list of superblocks in a cache of the memory device 240. In some embodiments, the cache is managed by a host driver of the host device 220, and called a host managed cache (HMC).

In some embodiments, the memory device 240 includes a single-level cell (SLC) NAND flash memory chip, and each memory cell stores a single data bit. In some embodiments, the memory device 240 includes a multi-level cell (MLC) NAND flash memory chip, and each memory cell of the MLC NAND flash memory chip stores 2 data bits. In an example, each memory cell of a triple-level cell (TLC) NAND flash memory chip stores 3 data bits. In another example, each memory cell of a quad-level cell (QLC) NAND flash memory chip stores 4 data bits. In yet another example, each memory cell of a penta-level cell (PLC) NAND flash memory chip stores 5 data bits. In some embodiments, each memory cell can store any suitable number of data bits (e.g., X data bits, where X is greater than 5). Compared with the non-SLC NAND flash memory chips (e.g., MLC SSD, TLC SSD, QLC SSD, PLC SSD), the SSD that has SLC NAND flash memory chips operates with a higher speed, a higher reliability, and a longer lifespan, and however, has a lower device density and a higher price.

Each memory channel 204 is coupled to a respective channel controller 214 (e.g., controller 214A, 214B, or 214N) configured to control internal and external requests to access memory cells in the respective memory channel 204. In some embodiments, each memory package 206 (e.g., each memory die) corresponds to a respective queue 216 (e.g., queue 216A, 216B, or 216N) of memory access requests. In some embodiments, each memory channel 204 corresponds to a respective queue 216 of memory access requests. Further, in some embodiments, each memory channel 204 corresponds to a distinct and different queue 216 of memory access requests. In some embodiments, a subset (less than all) of the plurality of memory channels 204 corresponds to a distinct queue 216 of memory access requests. In some embodiments, all of the plurality of memory channels 204 of the memory device 240 corresponds to a single queue 216 of memory access requests. Each memory access request is optionally received internally from the memory device 240 to manage the respective memory channel 204 or externally from the host device 220 to write or read data stored in the respective channel 204. Specifically, each memory access request includes one of: a system write request that is received from the memory device 240 to write to the respective memory channel 204, a system read request that is received from the memory device 240 to read from the respective memory channel 204, a host write request that originates from the host device 220 to write to the respective memory channel 204, and a host read request that is received from the host device 220 to read from the respective memory channel 204. It is noted that system read requests (also called background read requests or non-host read requests) and system write requests are dispatched by a memory controller 202 to implement internal memory management functions including, but are not limited to, garbage collection, wear levelling, read disturb mitigation, memory snapshot capturing, memory mirroring, caching, and memory sparing. In some embodiments, each of a host write request and a host read request corresponds to a respective input/output (I/O) access operation. Alternatively, in some embodiments, each of a system read request, a system write request, a host write request, and a host read request corresponds to a respective input/output (I/O) access operation

In some embodiments, in addition to the channel controllers 214, the controller 202 further includes a local memory processor 218, a host interface controller 222, an SRAM buffer 224, and a DRAM controller 226. The local memory processor 218 accesses the plurality of memory channels 204 based on the one or more queues 216 of memory access requests. In some embodiments, the local memory processor 218 writes into and read from the plurality of memory channels 204 on a memory block basis. Data of one or more memory blocks are written into, or read from, the plurality of channels jointly. No data in the same memory block is written concurrently via more than one operation. Each memory block optionally corresponds to one or more memory pages. In an example, each memory block to be written or read jointly in the plurality of memory channels 204 has a size of 16 KB (e.g., one memory page). In another example, each memory block to be written or read jointly in the plurality of memory channels 204 has a size of 64 KB (e.g., four memory pages). In some embodiments, each memory block has a size corresponding to a plurality of pages distinct from 16 KB and 64 KB. In some embodiments, each page has 16 KB user data and 2 KB metadata. Additionally, a number of memory blocks to be accessed jointly and a size of each memory block are configurable for each of the system read, host read, system write, and host write operations.

In some embodiments, the local memory processor 218 stores data to be written into, or read from, each memory block in the plurality of memory channels 204 in an SRAM buffer 224 of the controller 202. Alternatively, in some embodiments, the local memory processor 218 stores data to be written into, or read from, each memory block in the plurality of memory channels 204 in a DRAM buffer 228A that is included in memory device 240, e.g., by way of the DRAM controller 226. Alternatively, in some embodiments, the local memory processor 218 stores data to be written into, or read from, each memory block in the plurality of memory channels 204 in a DRAM buffer 228B that is main memory used by the processor module 102 (FIG. 1). The local memory processor 218 of the controller 202 accesses the DRAM buffer 228B via the host interface controller 222.

In some embodiments, data in the plurality of memory channels 204 is grouped into coding blocks, and each coding block is called a codeword. For example, each codeword includes n bits among which k bits correspond to user data and (n-k) corresponds to integrity data of the user data, where k and n are positive integers. In some embodiments, the memory device 240 includes an integrity engine 230 (e.g., an LDPC engine) and registers 232, which include a plurality of registers or SRAM cells or flip-flops and are coupled to the integrity engine 230. The integrity engine 230 is coupled to the memory channels 204 via the channel controllers 214 and SRAM buffer 224. Specifically, in some embodiments, the integrity engine 230 has data path connections to the SRAM buffer 224, which is further connected to the channel controllers 214 via data paths that are controlled by the local memory processor 218. The integrity engine 230 is configured to verify data integrity and correct bit errors for each coding block of the memory channels 204.

In some embodiments, the memory system 200 includes an SSD having an L2P address indirection table 250 that stores physical addresses for a set of logical addresses, e.g., a logical block address (LBA). In some embodiments, the L2P address indirection table 250 is stored in an L2P table cache 212 included in the controller 202. Alternatively, in some embodiments, the memory system 200 includes a DRAM buffer 228A, and the L2P address indirection table 250 is stored in the DRAM buffer 228A. The local memory processor 218 of the controller 202 accesses the DRAM buffer 228A via a DRAM controller 226.

During an SSD operation, data is temporarily stored in the DRAM buffer 228A or SRAM buffer 224 in the SSD to reduce the performance gap between the host 220 and the memory channels 204 (e.g., NAND flash memory). The buffers 228A and 224 are volatile and cannot hold data without an external power supply. In a normal power off process, a STANDBY command is transmitted to the memory device 240, and in response to the STANDBY command, data may be flushed from the buffer 228A or 224 to the memory channels 204, updating the latest metadata and user data. Conversely, in some situations, a data flushing process may not be completed, when an unexpected sudden power loss, such as unplugging the power to the system without prior notification, unexpected power outages, sudden battery loss or unplugging devices from the system. Further, under some circumstances, depending on the type of cached data in the buffer 228A or 224, the sudden power loss can cause serious device failure.

In some embodiments, the memory system 200 includes a power management system 280 configured to implement PLP operations to protect data in the memory device 240 (e.g., SSD) against sudden power loss. A dedicated capacitor component (e.g., a PLP capacitor, a bank of PLP capacitors) is applied to create more time for a data flushing process (e.g., moving data stored in the buffer 228A or 224 to the memory channels 204) under sudden power loss situations. The dedicated capacitor component is charged in an operation state of the memory device 240, and offers charged power to the memory device 240 in a PLP state when external power is off, such that the data flushing operation of the memory device 240 can be completed.

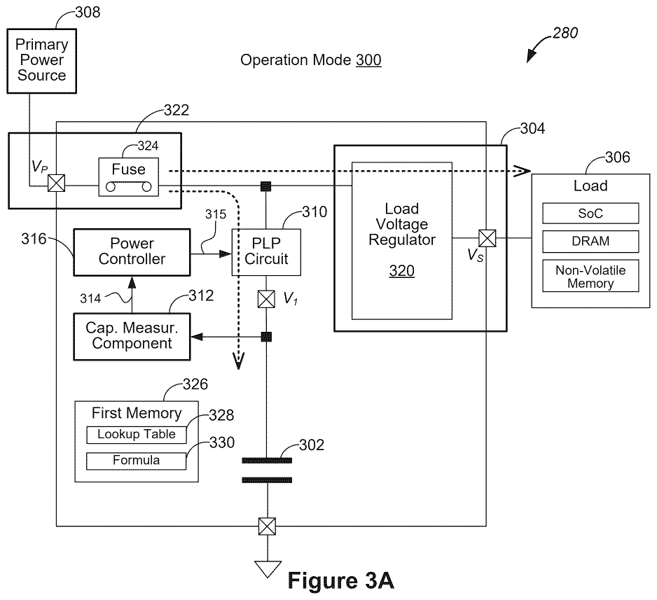

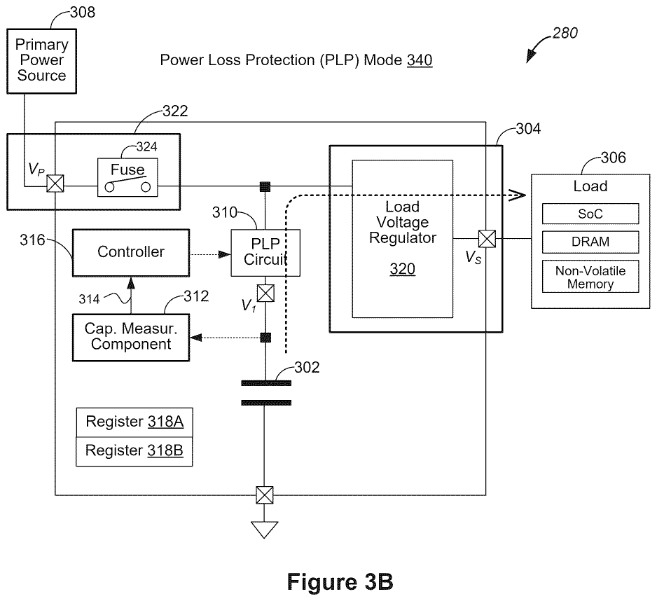

FIG. 3A is a block diagram of an example power management system 280 having an operation mode 300 in which a PLP capacitor 302 is charged, in accordance with some embodiments, and FIG. 3B is a block diagram of an example power management system 280 having a PLP mode 340 in which a PLP capacitor 302 discharges to provide power, in accordance with some embodiments. In some embodiments, the PLP capacitor 302 includes a plurality of PLP capacitor units (also called a bank of PLP capacitors) forming the PLP capacitor 302 jointly. The power management system 280 includes a load interface 304 configured to supply an operating supply voltage V_{S} to a load 306. The PLP capacitor 302 is coupled to the load interface 304, and configured to store electric energy E₀ provided to power the load 306 when a primary power source 308 is unavailable. A PLP circuit 310 is coupled to the load interface 304 and the PLP capacitor 302, and configured to charge the PLP capacitor 302 to a first supply voltage V₁ and store the electric energy E₀ when the primary power source 308 of the load is available. A capacitance measurement component 312 is coupled to the PLP capacitor 302, and configured to generate capacitance data 314 indicating a capacitance C of the PLP capacitor 302. A power controller 316 is coupled to the capacitance measurement component 312 and the PLP circuit 310, and configured to control charging of the PLP capacitor 302 and adjust the first supply voltage V₁ of the PLP capacitor 302 based on the capacitance C of the PLP capacitor 302.

Referring to FIG. 3A, in the operation mode 300, the primary power source 308 is available and electrically coupled to the load 306. The primary power source 308 provides power needed for operations of the load 306 (e.g., write to memory units, read from memory units, performance of internal memory management functions). The primary power source 308 charges the PLP capacitor 302 to the first supply voltage V₁, thereby storing the electric energy E₀ within the PLP capacitor 302. Referring to FIG. 3B, in the PLP mode 340, the primary power source 308 is unavailable to the load 306, and electrically decoupled from the load 306. The PLP capacitor 302 discharges to provide the electric energy E₀ to the load 306 to implement one or more secure power down operations. In some embodiments, the load interface 304 further includes a load voltage regulator 320 configured to convert a primary supply voltage V_{P} provided by the primary power source 308 to the operating supply voltage V_{S} when the primary power source 308 is available, and convert the first supply voltage V₁ provided by the PLP capacitor 302 to the operating supply voltage V_{S} when the primary power source 308 is not available.

In some embodiments, the power controller 316 is configured to adjust the first supply voltage V₁ of the PLP capacitor 302 by at least generating a regulator control signal 315 based on the capacitance data 314 and controlling the PLP circuit with the regulator control signal 315. In some embodiments, the capacitance measurement component 312 stores the capacitance data 314 in an associated register 318A. The power controller 316 executes a firmware program to extract the capacitance data 314 from the register 318A, and process the capacitance data 314. In some embodiments, the power controller 316 determines supply data corresponding to the first supply voltage V₁, and stores the supply data in an associated register 318B. The power controller 316 executes a firmware program to extract the supply data and control the PLP circuit 310 to generate the first supply voltage V1 at the PLP capacitor 302 based on the supply data.

In some embodiments, the power management system 280 further includes a power interface 322 coupled to the primary power source 308 and the PLP circuit 310. The PLP circuit 310 is disabled from maintaining the first supply voltage V₁, when the primary power source 308 of the load 306 is unavailable (e.g., decoupled or disconnected by a fuse 324). The power controller 316 is configured to determine a type of the load 306 (e.g., at a startup of a memory device) and adjust the first supply voltage V₁ based on both the capacitance data 314 and the type of the load 306. For example, a first type of memory device and a second type of memory device may require different levels of electric energy E₀ to complete a sequence of power down operations, and the power controller 316 may adaptively sets the first supply voltage V₁ based on a condition of the PLP capacitor 302 and the type of the memory device to be powered by the PLP capacitor 302.

In some embodiments, the load 306 requires a power down energy E_{T} (also called a target energy) to implement a set of secure power down operations, and the first supply voltage V₁ is adjusted such that a usable portion of the electric energy E₀ stored by the PLP capacitor 302 is substantially equal to the power down energy E_{T}. Alternatively, in some embodiments, the usable portion of the electric energy E₀ stored by the PLP capacitor 302 is substantially greater than the power down energy E_{T}, e.g., equal to a sum of the power down energy E_{T} and an energy margin. For example, the energy margin is 10% of the power down energy E_{T}. Stated another way, the PLP capacitor 302 is overprovisioned in a controlled manner without significantly impacting the lifetime of the PLP capacitor 302.

In some embodiments, the load 306 requires a power down energy E_{T} to implement a set of secure power down operations including a first subset of secure power down operations (e.g., memory read operations) and a second subset of secure power down operations (e.g., memory write operations). The second subset of secure power down operations has a higher priority level than that of the first subset of secure power down operations. For instance, the second subset of secure power down operations is implemented before the first subset of secure power down operations. The load 306 is configured to implement the second subset of secure power down operations in accordance with a determination that a usable portion of the electric energy E₀ drops below the power down energy E_{T}. In other words, when the usable portion of the electric energy E₀ is limited, the second subset of secure power down operations are prioritized over the first subset of secure power down operations.

In some embodiments, the load 306 requires a power down energy E_{T} to implement a set of secure power down operations. The power management system 280 may determine that a usable portion of the electric energy E₀ drops below the power down energy E_{T}. The usable portion of the electric energy E₀ may not be sufficient to complete the set of secure power down operations. An energy low indication signal may be enabled to indicate that the electric energy E₀ is low. Referring to FIG. 3A, in the operation state, the primary power source 308 is coupled to the power management system 308. In response to the energy low indication signal, the controller may control the PLP circuit 310 to increase the first supply voltage V₁, thereby increasing the electric energy E₀ stored in the PLP capacitor 302.

In some embodiments, the load 306 includes at least a memory controller 202 (FIG. 2) coupled to a non-volatile memory (e.g., NAND flash memory cells). The memory controller 202 is configured to access the non-volatile memory to write data into, and read the data from, the non-volatile memory. Referring to FIG. 3B, when the primary power source 308 of the load 306 is unavailable, the memory controller 202 is powered by the electric energy E₀ to at least buffer data stored in a cache buffer (e.g., SRAM buffer 224 and DRAM buffer 228A in FIG. 2) to a subset of the non-volatile memory and update an address mapping table.

More specifically, in some embodiments, the power management system 280 is included in a memory device 240 (FIG. 2). An example of the memory device 240 is an SSD. The memory device 240 includes a non-volatile memory storing data in a plurality of memory cells (e.g., NAND flash memory cells), which are organized in a plurality of memory channels 204. The memory controller 202 coupled to the non-volatile memory, and configured to access the plurality of memory cells to write the data into the plurality of memory cells and read the data from the plurality of memory cells. The power management system 280 is coupled to the memory controller 240, and configured to provide the operating supply voltage V_{S} to power the memory controller 202 (e.g., in the PLP mode 340). The load 306 includes at least the memory controller 202 (e.g., implemented in a System on a Chip (SoC)). The primary power source 308 of the load 306 is coupled to the power management system 280. When the primary power source 308 is unavailable, the memory controller 202 is driven by the operating supply voltage V_{S} generated by the power management system 280, e.g., powered by the electric energy E₀ stored in PLP capacitor 302.

A target energy E_{T} (also called a power down energy E_{T}) is needed to complete operations (e.g., data flushing) of the memory device 240 when a primary power source is unavailable (e.g., at a sudden power loss), and the PLP capacitor 302 is configured to store at least the target energy E and provide power to the memory device 240 to complete the operations. The target energy E is proportional to a product of the capacitance C of the PLP capacitor 302 and a square of the voltage level V₀ of the PLP capacitor 302 as follows:

$${E}_{T} = \frac{1}{2} {CV}_{0}^{2} . \qquad ( 1 )$$

In some embodiments, the target energy E is known, and the operating V_{C} of the PLP capacitor 302 is measured. The capacitance C of the PLP capacitor 302 is determined based on the operating V₀ of the PLP capacitor 302 as follows:

$${V}_{0} = \sqrt{\frac{2 {E}_{T}}{C}} . \qquad ( 2 )$$

In some embodiments, a firmware program is executed to control the power management system 280 to measure the voltage level V_{C} and determine the capacitance C of the PLP capacitor 302. For each time the capacitance of the PLP capacitor 302 is determined, an operating voltage V_{O} of the PLP capacitor 302 is determined to maintain the target energy E. In some embodiments, the PLP capacitor 302 includes Ta-P, and a voltage acceleration factor (VAF) is determined to characterize an aging rate of the Ta-P based PLP capacitor 302. For example, the VAF is determined as (V_{C}/V_{O})¹⁶, where V_{C} is a category voltage and V_{O} is the operating Voltage. In some embodiments, the PLP capacitor 302 is overprovisioned to operate at 28 V during an entire lifetime of the memory device 240. In some embodiments, the operating voltage is equal to 24 V early in a lifetime of the memory device 240. The PLP capacitor 302 operates at 24 V initially and increases during the lifetime of the memory device 240, thereby avoiding overprovisioning and extending the lifetime of the PLP capacitor 302 (e.g., by up to ten years).

In some embodiments, the first supply voltage V₁ supplied by the PLP capacitor 302 has a first voltage level at a first time and a second voltage level at a second time. The first voltage level is earlier than the second time in a lifetime of the PLP capacitor 302, and the first voltage level is lower than the second voltage level. Stated another way, the first supply voltage V₁ driving the PLP capacitor 302 increases gradually over time to compensate for a capacitance loss associated with degradation of the PLP capacitor 302.

Referring to FIG. 3A, in some embodiments, the PLP capacitor 302 is charged based on information stored in a first memory 326, e.g., one-time-programmable memory (OTP). Further, in some embodiments, the first memory 326 stores a lookup table 328 that maps a voltage level of the first supply voltage V₁ to the capacitance of the PLP capacitor 302. After the capacitance of the PLP capacitor 302 is measured, the lookup table 328 is checked to find a target voltage level of the first supply voltage V₁ associated with the corresponding capacitance data 314. Alternatively, in some embodiments, the first memory 326 stores a formula 330 (e.g., equation (2)) that correlates a voltage level of the first supply voltage V₁ to the capacitance of the PLP capacitor 302. After the capacitance of the PLP capacitor 302 is measured, the formula 330 is applied to determine a target voltage level of the first supply voltage V₁ associated with the corresponding capacitance data 314.

In some embodiments, the load interface 304, the PLP circuit 310, the power controller 316, and the capacitance measurement component 312 are formed on an integrated circuit. Further, in some embodiments, the PLP capacitor 302 is fabricated on the integrated circuit. Alternatively, in some embodiments, the PLP capacitor 302 is mounted on the integrated circuit in a hybrid manner.

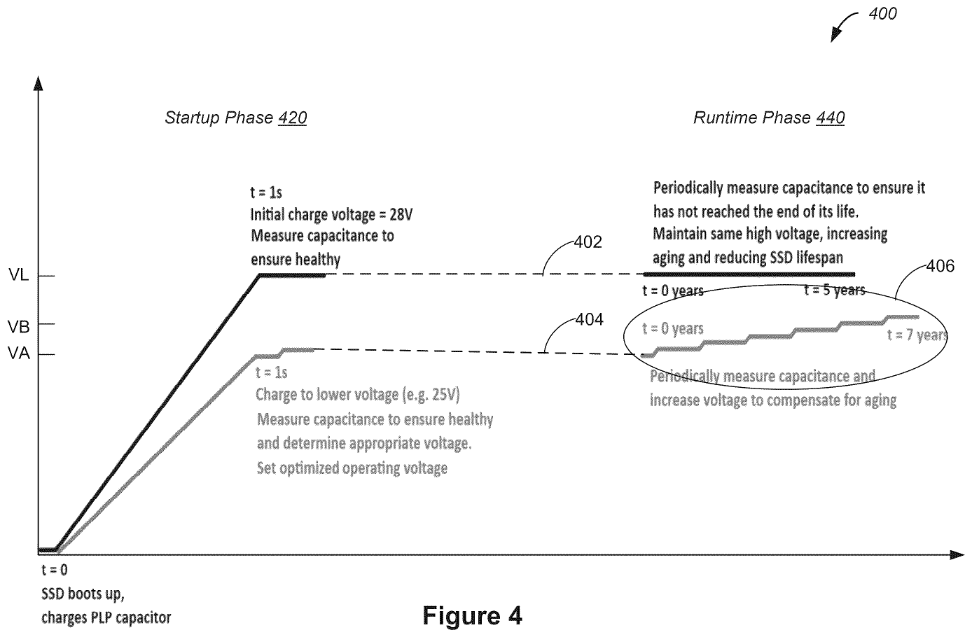

FIG. 4 is a temporal diagram 400 of an example first supply voltage V₁ of a PLP capacitor 302 during a startup phase 420 and a runtime phase 440, in accordance with some embodiments. The temporal diagram 400 shows a first curve 402 and a second curve 404 of the first supply voltage V₁ of the PLP capacitor 302. The first curve 402 corresponds to the PLP capacitor 302 in an overprovisioned condition, while the second curve 404 corresponds to the PLP capacitor 302 having the first supply voltage V₁ adaptively adjusted during a lifetime of the PLP capacitor 302. In some embodiments, the startup phase 420 includes a predefined duration of time (e.g., 1 second). In some embodiments, in accordance with the first curve 402, the first supply voltage V₁ may be overprovisioned to a supply voltage limit VLH (e.g., 28 V) at the end of each startup phase 420, and stay at the supply voltage limit VLH in the runtime phase 440 during a lifetime of the PLP capacitor 302. Capacitance of the PLP capacitor 302 may be measured to determine whether the PLP capacitor 302 is healthy, whether the PLP capacitor 302 has reached an end of its lifetime, or whether the PLP capacitor 302 needs to be replaced.

In some embodiments not shown, the first supply voltage V₁ may be charged to a voltage level (e.g., 25 V) that is lower than the supply voltage limit VLH (e.g., 28 V) at the end of each startup phase 420, and stays at the same voltage level during the immediately runtime phase 440. Alternatively, in some embodiments, in accordance with the second curve 404, the first supply voltage V₁ may be charged to a voltage level (e.g., 25 V) that is lower than the supply voltage limit VLH (e.g., 28 V) at the end of each startup phase 420, and adaptive adjusted to a distinct voltage level (e.g., a higher voltage level of 26V) during the immediately following runtime phase 440. Additionally, in some embodiments, the voltage level of the first supply voltage V₁ is adaptively determined based on the capacitance of the PLP capacitor 302, and keeps an increasing trend 406 among different runtime phases 440 of the lifetime of the PLP capacitor 302.

In some embodiments, the capacitance of the PLP capacitor 302 is measured in a particular startup phase 420 to determine a target voltage level VB, and the first supply voltage V₁ of the PLP capacitor reaches the target voltage level VB at the end of the startup phase 420 and stays at the target voltage level in an immediately following runtime phase, until the load 306 is shut down. Alternatively, in some embodiments, the first supply voltage V₁ of the PLP capacitor 302 reaches a predefined startup voltage level VA at the end of the startup phase 420. The capacitance of the PLP capacitor 302 is measured in the startup phase 420 or an immediately following runtime phase 440 to determine a target voltage level VB. The first supply voltage V₁ of the PLP capacitor 302 is adjusted to, and stays at, the target voltage level VB in the runtime phase 440, until the load 306 is shut down.

The power management system 280 may measure capacitance of the PLP capacitor 302 and dynamically adjusts the first supply voltage V₁ of the PLP capacitor 302. In some embodiments, a power controller 316 executes a firmware program to measure the capacitance of the PLP capacitor 302. In some embodiments, the first supply voltage V₁ of the PLP capacitor is adjusted according to a schedule (e.g., on selected dates), periodically (e.g., every two weeks), or in response to a user request. In an example, the first supply voltage V₁ of a PLP capacitor 302 is adjusted on a yearly basis, while capacitance measurement occurs at a higher frequency. More specifically, in some embodiments, capacitance data are generated to indicate the capacitance of the PLP capacitor 302 at a first frequency (e.g., during each startup), and the first supply voltage V1 of the PLP capacitor 302 is adjusted at a second frequency (e.g., every three months) that is lower than the first frequency.

In some embodiments, in an operation mode 300 (FIG. 3A), the first supply voltage V1 includes a direct current (DC) voltage level and a ripple voltage component superimposed onto the DC voltage level. The capacitance measurement component 312 may monitor a voltage ripple level and a ripple drop time of the first supply voltage V1 to determine the capacitance data indicating the capacitance of the PLP capacitor 302. A lookup table 328 or a formula 330 is applied to determine whether the first supply voltage V1 needs to be adjusted based on the capacitance data.

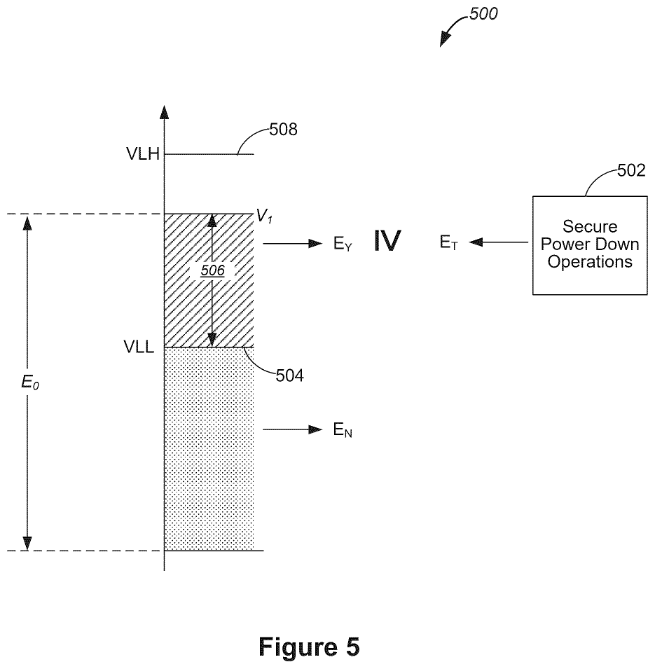

FIG. 5 is a diagram showing a change 500 of electrical energy E₀ stored in an PLP capacitor 302, in accordance with some embodiments. The PLP circuit 310 charges the PLP capacitor 302 to a first supply voltage V₁ to store the electric energy E₀ when a primary power source 308 of a load 306 is available. In some embodiments, the load 306 requires a power down energy E_{T} to implement a set of secure power down operations 502. When the electric energy E₀ is being consumed during a PLP mode 340, a voltage level of the first supply voltage V₁ gradually drops. When the first supply voltage V₁ drops to a low supply limit VLL, the set of secure power down operations 502 cannot be implemented. A corresponding voltage drop from the first supply voltage V₁ to the low supply limit VLL corresponds to a usable portion E_{Y} of the electric energy E₀. The electric energy E₀ and the first supply voltage V₁ are selected such that the usable portion E_{Y} of the electric energy E₀ is equal to or greater than the power down energy E_{T} needed to implement the set of secure power down operations 502. In some embodiments, the electric energy E₀ includes only the usable portion E_{Y}, and a complementary un-usable portion E_{N} is equal to 0. Alternatively, in some embodiments, the electric energy E₀ includes both the usable portion E_{Y} and a complementary un-usable portion E_{N}, which is not equal to 0.

Stated another way, in some embodiments, the load 306 corresponds to a first operating level 504 (e.g., the low supply limit VLL) of the first supply voltage V₁, and the first supply voltage V₁ is required to stay above the first operating level 504 to allow the load 306 to operate properly, and a usable portion E_{Y} of the electric energy E₀ stored by the PLP capacitor 302 corresponds to a drop of the first supply voltage V₁ below the first operating level 504 (e.g., the low supply limit VLL). In some embodiments, the load 306 corresponds to an operating range 506 for the first supply voltage V₁, and the operating range 506 is defined between a first operating level 504 (e.g., the low supply limit VLL) and a second operating level 508 (e.g., a supply voltage limit VLH) higher than the first operating level 504, and the first supply voltage V₁ is closer to the first operating level 504 than to the second operating level 508. In some embodiments, reliability of the PLP capacitor 302 or the load 306 may be compromised when the first operating level 504 reaches or exceeds the second operating level 508 (e.g., a supply voltage limit VLH). By these means, the first supply voltage V₁ is never overprovisioned to the second operating level 508, and a lifetime of the PLP capacitor 302 may be expanded working below the second operating level 508.

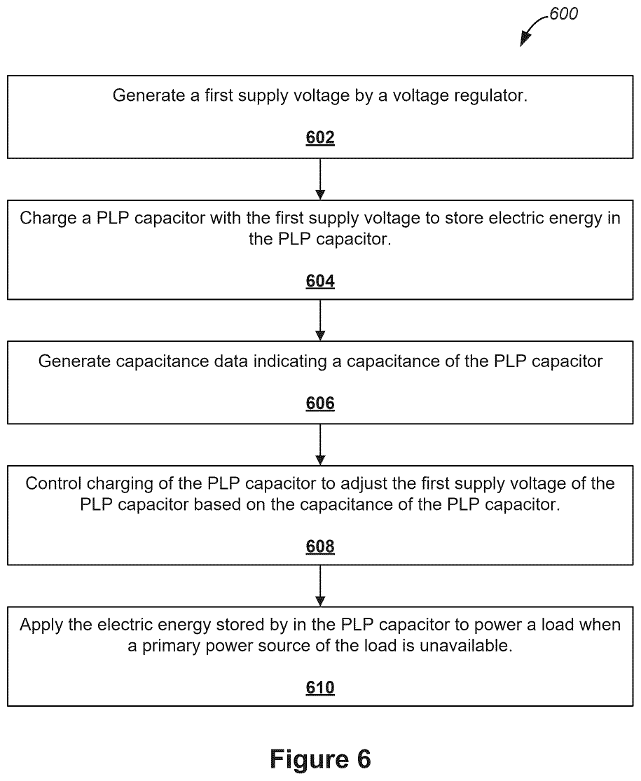

FIG. 6 is a flow diagram of an example method 600 for powering of a PLP capacitor 302 of an electronic device, in accordance with some embodiments. The method 600 is implemented by a power management system 280 280 (FIGS. 2, 3A, and 3B). The method 600 includes generating (operation 602) a first supply voltage V₁ by a PLP circuit 310, charging (operation 604) a PLP capacitor 302 with the first supply voltage V₁ to store electric energy E₀ in the PLP capacitor 302, generating (operation 606) capacitance data 314 indicating a capacitance of the PLP capacitor 302, controlling (operation 608) charging of the PLP capacitor 302 to adjust the first supply voltage V₁ of the PLP capacitor 302 based on the capacitance of the PLP capacitor 302, and applying (operation 610) the electric energy E₀ stored by in the PLP capacitor 302 to power a load 306 when a primary power source 308 of the load 306 is unavailable (e.g., due to a sudden power loss of the primary power source 308).

In some embodiments, the load 306 requires a power down energy E_{T} (also called the target energy E_{T}) to implement a set of secure power down operations 502. The method 600 further includes enabling an energy low indication signal indicating the electric energy E₀ is low, in accordance with a determination that a usable portion E_{Y} of the electric energy E₀ drops below the power down energy E_{T}.

In some embodiments, the load 306 corresponds to a first operating level 504 of the first supply voltage V₁ (FIG. 5), and the first supply voltage V₁ is required to stay above the first operating level 504 to allow the load 306 to operate properly, and a usable portion E_{Y} of the electric energy E₀ stored by the PLP capacitor 302 corresponds to a drop of the first supply voltage V₁ below the first operating level 504. Alternatively, in some embodiments, the load 306 corresponds to an operating range 506 for the first supply voltage V₁, and the operating range 506 is defined between a first operating level 504 and a second operating level 508 higher than the first operating level 504, and wherein the first supply voltage V₁ is closer to the first operating level 504 than to the second operating level 508.

In some embodiments, the method 600 further includes adjusting the first supply voltage V₁ of the PLP capacitor 302 by at least generating a regulator control signal 315 based on the capacitance data 314 and controlling the PLP circuit 310 with the regulator control signal 315.

In some embodiments, the method 600 further includes adjusting the first supply voltage V₁ of the PLP capacitor 302 according to a schedule, periodically, or in response to a user request.

In some embodiments, the method 600 includes extracting a lookup table 328 from a first memory 326. The lookup table 328 maps a voltage level of the first supply voltage V₁ to the capacitance of the PLP capacitor 302. The method 600 further includes adjusting the first supply voltage V₁ of the PLP capacitor 302 by checking the lookup table 328 based on the capacitance of the PLP capacitor 302. Alternatively, in some embodiments, the method 600 includes extracting a formula 330 from a first memory 326. The formula 330 correlates a voltage level of the first supply voltage V₁ with the capacitance of the PLP capacitor 302. The method 600 further includes adjusting the first supply voltage V₁ of the PLP capacitor 302 by applying the formula to determine the first supply voltage V₁ based on the capacitance of the PLP capacitor 302.

In some embodiments, the method 600 further includes storing data in a plurality of memory cells of a non-volatile memory, accessing by a memory controller 202 the plurality of memory cells to write the data into the plurality of memory cells and read the data from the plurality of memory cells, and providing an operating supply voltage V_{S} to power the memory controller 202. The load 306 includes at least the memory controller 202, and the primary power source 308 of the load 306 is coupled to the power management system 280. When the primary power source 308 is unavailable, the memory controller 202 is driven by the operating supply voltage V_{S} generated by the power management system 280.

In some embodiments, the load 306 includes at least a memory controller 202 coupled to a non-volatile memory. The method 600 further includes accessing the non-volatile memory to write data into, and read the data from, the non-volatile memory, and when the primary power source 308 of the load 306 is unavailable, powering the memory controller 202 by the electric energy E₀ to at least buffer data stored in a cache buffer (e.g., SRAM buffer 224, DRAM buffer 228A) to a subset of the non-volatile memory (e.g., for data flushing) and update an address mapping table. Further, in some embodiments, the electronic device is a solid-state drive (SSD), and the non-volatile memory includes a plurality of NAND flash memory cells.

In some embodiments, the PLP capacitor 302 includes a plurality of PLP capacitor 302 units forming the PLP capacitor 302 jointly.

In some embodiments, the method 600 further includes determining a type of the load 306 (e.g., at a startup of the electronic device) and adjusting the first supply voltage V₁ based on both the capacitance data 314 and the type of the load 306.

In some embodiments, the first supply voltage V₁ supplied by the PLP capacitor 302 has a first voltage level at a first time and a second voltage level at a second time. The first voltage level is earlier than the second time in a lifetime of the PLP capacitor 302. The first voltage level is lower than the second voltage level.

In some embodiments, a power interface is coupled to the primary power source 308 and the PLP circuit 310. The method 600 further includes disabling the PLP circuit 310 from maintaining the first supply voltage V₁, when the primary power source 308 of the load 306 is unavailable.

In some embodiments, the load interface 304 further includes a load voltage regulator 320. The method 600 further includes converting, by the regulator 320, a primary supply voltage provided by the primary power source 308 to the operating supply voltage V_{S} when the primary power source 308 is available. The method 600 further includes converting the first supply voltage V₁ provided by the PLP capacitor 302 to the operating supply voltage V_{S} when the primary power source 308 is not available.

It should be understood that the particular order in which the operations in FIG. 6 have been described are merely exemplary and are not intended to indicate that the described order is the only order in which the operations could be performed. One of ordinary skill in the art would recognize various ways to reorder the operations described herein. Additionally, it should be noted that details of other systems and processes described herein with respect to FIGS. 1-5 are also applicable in an analogous manner to method 600 described above with respect to FIG. 6. For brevity, these details are not repeated here.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. An electronic device, comprising:
a load interface configured to supply an operating supply voltage to a load;
a power loss protection (PLP) capacitor coupled to the load interface, the PLP capacitor configured to store electric energy provided to power the load when a primary power source is unavailable;
a PLP circuit coupled to the load interface and the PLP capacitor, wherein the PLP circuit is configured to charge the PLP capacitor to a first supply voltage and store the electric energy when the primary power source of the load is available;
a capacitance measurement component coupled to the PLP capacitor, the capacitance measurement component configured to generate capacitance data indicating a capacitance of the PLP capacitor; and
a power controller coupled to the capacitance measurement component and the PLP circuit, wherein the power controller is configured to control charging of the PLP capacitor and adjust the first supply voltage of the PLP capacitor based on the capacitance of the PLP capacitor.

2. The electronic device of claim 1, wherein the load requires a power down energy to implement a set of secure power down operations, and the first supply voltage is adjusted such that a usable portion of the electric energy stored by the PLP capacitor is substantially equal to the power down energy.

3. The electronic device of claim 1, wherein the load requires a power down energy to implement a set of secure power down operations, and the first supply voltage is adjusted based on the capacitance data, such that a usable portion of the electric energy stored by the PLP capacitor is greater than the power down energy.

4. The electronic device of claim 1, wherein:
the load requires a power down energy to implement a set of secure power down operations including a first subset of secure power down operations and a second subset of secure power down operations;
the second subset of secure power down operations has a higher priority level than that of the first subset of secure power down operations; and
the load is configured to implement the second subset of secure power down operations in accordance with a determination that a usable portion of the electric energy drops below the power down energy.

5. The electronic device of claim 1, wherein:
the load requires a power down energy to implement a set of secure power down operations; and
the electronic device is configured to enable an energy low indication signal indicating the electric energy is low, in accordance with a determination that a usable portion of the electric energy drops below the power down energy.

6. The electronic device of claim 1, wherein the load corresponds to a first operating level of the first supply voltage, and the first supply voltage is required to stay above the first operating level to allow the load to operate properly, and a usable portion of the electric energy stored by the PLP capacitor corresponds to a drop of the first supply voltage below the first operating level.

7. The electronic device of claim 1, wherein the load corresponds to an operating range for the first supply voltage, and the operating range is defined between a first operating level and a second operating level higher than the first operating level, and wherein the first supply voltage is closer to the first operating level than to the second operating level.

8. The electronic device of claim 1, wherein the power controller is configured to adjust the first supply voltage of the PLP capacitor by at least generating a regulator control signal based on the capacitance data and controlling the PLP circuit with the regulator control signal.

9. The electronic device of claim 1, wherein the first supply voltage of the PLP capacitor is adjusted according to a schedule, periodically, or in response to a user request.

10. The electronic device of claim 1, further comprising a first memory storing a lookup table, the lookup table mapping a voltage level of the first supply voltage to the capacitance of the PLP capacitor.

11. The electronic device of claim 1, further comprising a first memory storing a formula, the formula correlating a voltage level of the first supply voltage with the capacitance of the PLP capacitor.

12. The electronic device of claim 1, further comprising:
a non-volatile memory storing data in a plurality of memory cells;
a memory controller coupled to the non-volatile memory, the memory controller configured to access the plurality of memory cells to write the data into the plurality of memory cells and read the data from the plurality of memory cells; and
a power management system coupled to the memory controller, the power management system configured to provide the operating supply voltage to power the memory controller;
wherein the load includes at least the memory controller, and the primary power source of the load is coupled to the power management system; and
wherein when the primary power source is unavailable, the memory controller is driven by the operating supply voltage generated by the power management system.

13. The electronic device of claim 1, wherein:
the load includes at least a memory controller coupled to a non-volatile memory;
the memory controller is configured to access the non-volatile memory to write data into, and read the data from, the non-volatile memory; and
when the primary power source of the load is unavailable, the memory controller is powered by the electric energy to at least buffer data stored in a cache buffer to a subset of the non-volatile memory and update an address mapping table.

14. The electronic device of claim 13, wherein the electronic device is a solid-state drive (SSD), and the non-volatile memory includes a plurality of NAND flash memory cells.

15. The electronic device of claim 1, wherein the PLP capacitor includes a plurality of PLP capacitor units forming the PLP capacitor jointly.

16. The electronic device of claim 1, wherein the power controller is configured to determine a type of the load and adjust the first supply voltage based on both the capacitance data and the type of the load.

17. The electronic device of claim 1, wherein:
the first supply voltage supplied by the PLP capacitor has a first voltage level at a first time and a second voltage level at a second time;
the first voltage level is earlier than the second time in a lifetime of the PLP capacitor; and
the first voltage level is lower than the second voltage level.

18. The electronic device of claim 1, further comprising:
a power interface coupled to the primary power source and the PLP circuit, wherein the PLP circuit is disabled from maintaining the first supply voltage, when the primary power source of the load is unavailable.

19. The electronic device of claim 1, wherein the load interface further comprises a load voltage regulator configured to convert a primary supply voltage provided by the primary power source to the operating supply voltage when the primary power source is available, and convert the first supply voltage provided by the PLP capacitor to the operating supply voltage when the primary power source is not available.

20. A method, comprising:
generating a first supply voltage by a PLP circuit;
charging a PLP capacitor with the first supply voltage to store electric energy in the PLP capacitor;
generating capacitance data indicating a capacitance of the PLP capacitor;
controlling charging of the PLP capacitor to adjust the first supply voltage of the PLP capacitor based on the capacitance of the PLP capacitor; and
applying the electric energy stored by in the PLP capacitor to power a load when a primary power source of the load is unavailable.
